(19) United States
(12) Patent Application Publication
(10) Pub. No.: US 2026/0115807 A1
(43) Pub. Date: Apr. 30, 2026

(54) CUTTING TOOL

(71) Applicant: Sumitomo Electric Industries, Ltd., Osaka-shi, Osaka (JP)

(72) Inventors: Haruyo FUKUI, Osaka-shi, Osaka (JP); Nozomi TSUKIHARA, Osaka-shi, Osaka (JP); Toshihiro TABATA, Osaka-shi, Osaka (JP); Hiroyoshi MOMIDA, Osaka-shi, Osaka (JP); Takahiro YAMASAKI, Osaka-shi, Osaka (JP)

(73) Assignee: Sumitomo Electric Industries, Ltd., Osaka-shi, Osaka (JP)

(21) Appl. No.: 19/134,305

(22) PCT Filed: Oct. 31, 2024
(86) PCT No.: PCT/JP2024/038909

§ 371 Date: May 30, 2025

(51) Int. Cl. B23B 27/14; C23C 14/06; C23C 14/32

(52) U.S. Cl. CPC B23B 27/148; C23C 14/0641; C23C 14/32; B23B 2228/105

(57) ABSTRACT

A cutting tool includes: a substrate; and a coating film disposed on the substrate, wherein the coating film includes a first layer, the first layer consists of an alternating layer in which a first unit layer and a second unit layer are alternately stacked, the first unit layer consists of Ti_{1-a-b}AlₐSc_{b}N, the a is 0.350 or more and 0.650 or less, the b is 0.010 or more and 0.100 or less, the second unit layer consists of Al_{c}V_{1-c}N, the c is 0.40 or more and 0.75 or less, and the a and the c satisfy a relation of c>a.

### TECHNICAL FIELD

The present disclosure relates to a cutting tool.

### BACKGROUND ART

Conventionally, a cutting tool including a substrate and a coating film that coats the substrate has been used for cutting. For example, each of PTL 1 and PTL 2 discloses a cutting tool in which a substrate is coated with a coating film formed by adding, to a nitride or carbonitride including Ti and Al as main components, one or more elements selected from a group consisting of a group 4 element, a group 5 element, a group 6 element, Si, Y, and a rare earth element.

### CITATION LIST

### Patent Literature

PTL 1: WO 1997/034023
PTL 2: Japanese Patent Laying-Open No. 2015-54995

### SUMMARY OF INVENTION

A cutting tool according to the present disclosure is a cutting tool comprising: a substrate; and a coating film disposed on the substrate, wherein the coating film includes a first layer, the first layer consists of an alternating layer in which a first unit layer and a second unit layer are alternately stacked, the first unit layer consists of Ti_{1-a-b}AlₐSc_{b}N, the a is 0.350 or more and 0.650 or less, the b is 0.010 or more and 0.100 or less, the second unit layer consists of Al_{c}V_{1-c}N, the c is 0.40 or more and 0.75 or less, and the a and the c satisfy a relation of c>a.

### BRIEF DESCRIPTION OF DRAWINGS

FIG. 1 is a schematic enlarged cross sectional view of an exemplary cutting tool according to a first embodiment.

FIG. 2 is a schematic enlarged cross sectional view of another exemplary cutting tool according to the first embodiment.

FIG. 3 is a schematic enlarged cross sectional view of another exemplary cutting tool according to the first embodiment.

FIG. 4 is a schematic enlarged cross sectional view of another exemplary cutting tool according to the first embodiment.

FIG. 5 is a diagram for illustrating an exemplary ratio of thicknesses of a first unit layer and a second unit layer.

FIG. 6 is a schematic enlarged cross sectional view of an exemplary cutting tool according to a second embodiment.

FIG. 7 is a schematic enlarged cross sectional view of another exemplary cutting tool according to the second embodiment.

FIG. 8 is a schematic enlarged cross sectional view of another exemplary cutting tool according to the second embodiment.

FIG. 9 is a schematic enlarged cross sectional view of another exemplary cutting tool according to the second embodiment.

FIG. 10 is a diagram for illustrating an exemplary ratio of thicknesses of a first unit layer and a third unit layer.

FIG. 11 is a schematic cross sectional view of a cathode arc ion plating apparatus used in Examples.

FIG. 12 is a schematic top view of the cathode arc ion plating apparatus shown in FIG. 11.

### DETAILED DESCRIPTION

### Problem to be Solved by the Present Disclosure

In recent years, in response to an increase in demand for electric vehicles as well as pervasion of AI (Artificial Intelligence) or 5G (5th Generation Mobile Communication System), there has been an increasing need for cutting of parts used for these purposes of use. From the viewpoint of corrosion resistance and functionality, examples of materials for the parts for these purposes of use include difficult-to-cut materials such as a heat-resistant alloy (for example, a nickel-based alloy and a titanium alloy) and a ceramic.

Each of the difficult-to-cut materials such as the heat-resistant alloy is a material onto which it is difficult to perform high-efficiency processing because the difficult-to-cut material has high hardness, is likely to be hardened due to processing, has a large cutting resistance, and is a material having a small heat conductivity and therefore has a high cutting edge temperature at the time of cutting. In order to solve this problem, new techniques are being developed, such as an ultrahigh-pressure cutting liquid supplying method, vibration cutting, and freezing cutting. However, wear of a tool is basically a major problem in cutting such a difficult-to-cut material, and therefore there has been a great expectation for development of a new tool material.

Thus, an object of the present disclosure is to provide a cutting tool that can have an excellent tool life particularly even under such cutting conditions that a cutting edge temperature becomes high. [Advantageous Effect of the Present Disclosure]

According to the present disclosure, it is possible to provide a cutting tool that can have an excellent tool life particularly even under such cutting conditions that a cutting edge temperature becomes high.

### DESCRIPTION OF EMBODIMENTS

First, embodiments of the present disclosure will be listed and described.

(1) A cutting tool according to the present disclosure is a cutting tool comprising: a substrate; and a coating film disposed on the substrate, wherein the coating film includes a first layer, the first layer consists of an alternating layer in which a first unit layer and a second unit layer are alternately stacked, the first unit layer consists of Ti_{1-a-b}AlₐSc_{b}N, the a is 0.350 or more and 0.650 or less, the b is 0.010 or more and 0.100 or less, the second unit layer consists of Al_{c}V_{1-c}N, the c is 0.40 or more and 0.75 or less, and the a and the c satisfy a relation of c>a.

According to the present disclosure, it is possible to provide a cutting tool that can have an excellent tool life particularly even under such cutting conditions that a cutting edge temperature becomes high. This is presumably due to the following reasons.

The Sc in the Ti_{1-a-b}AlₐSc_{b}N of the first unit layer is oxidized under the high-temperature cutting conditions, and a passivation consisting of Sc₂O₃ is generated in the coating film. Since the Sc₂O₃ has a very high melting point of 2485° C., the passivation consisting of Sc₂O₃ can be stably present even under the high-temperature cutting conditions. Therefore, stability of performance of the cutting tool is improved even under the high-temperature cutting conditions.

The Sc₂O₃ causes a so-called “keying on effect” in which the Sc₂O₃ is precipitated at a crystal grain boundary of TiAlScN, thereby preventing oxygen from being diffused from a surface of the coating film to inside of the coating film through the crystal grain boundary. With the keying on effect, oxidation resistance of the coating film is significantly improved. Further, with the keying on effect, reactivity between a workpiece and the coating film can be suppressed, with the result that a friction coefficient between the workpiece and the coating film can be reduced.

The lattice constant of the ScN is 4.51 Å, and is larger than the lattice constant of TiN, i.e., 4.23 Å, and the lattice constant of AlN, i.e., 4.12 Å. Therefore, since the Sc is present in the first unit layer, strain is introduced into the first unit layer, with the result that the structure of the first unit layer becomes fine. Thus, hardness of the first unit layer becomes high, thus resulting in improved wear resistance of the coating film including the first layer.

Each of PTL 1 and PTL 2 discloses a coating film in which yttrium is added to a nitride or carbonitride (hereinafter, also referred to as “TiAlN or TiAlCN”) including Ti and Al as main components. However, since the lattice constant of the YN is large, i.e., 4.88 Å, an amount of the YN that can be dissolved in TiAlN or TiAlCN in a solid state is limited. Therefore, in the TiAlN or TiAlCN to which the yttrium is added, an amount of strain introduced is insufficient, and the effect of attaining high hardness and improved wear resistance of the coating film is insufficient.

The hardness of the Ti_{1-a-b}AlₐSc_{b}N of the first unit layer is less likely to be decreased at a high temperature as compared with the Al_{c}V_{1-c}N of the second unit layer. Therefore, even at the high temperature, the first layer can maintain excellent wear resistance. Further, the Ti_{1-a-b}AlₐSc_{b}N has a larger compressive residual stress than that of the Al_{c}V_{1-c}N, thereby contributing to improvement of chipping resistance of the first layer.

The V in the Al_{c}V_{1-c}N of the second unit layer is oxidized under the high-temperature cutting conditions, and V₂O₅ is generated in the coating film. Since the melting point of the V₂O₅ is 690° C., the V₂O₅ is softened at a temperature at the time of cutting to have a function as a lubricant, thereby reducing a friction coefficient at a rake face of the tool. Therefore, the first layer including the second unit layer can improve adherence resistance, slidability, and wear resistance of the coating film in the processing in which the cutting edge has a high temperature.

The Al_{c}V_{1-c}N of the second unit layer has more excellent heat resistance than that of the Ti_{1-a-b}AlₐSc_{b}N of the first unit layer. Therefore, the first layer including the second unit layer can improve the heat resistance of the coating film.

The first layer consists of the alternating layer in which the first unit layer and the second unit layer are alternately stacked. Therefore, even under the high-temperature cutting conditions, the first layer can have the effect of improving the stability, oxidation resistance, wear resistance, and chipping resistance of the coating film by the first unit layer, and the effect of improving the adherence resistance, slidability, wear resistance, and heat resistance of the coating film by the second unit layer.

Another alloy element such as Cr is added to a difficult-to-cut material such as a nickel-based alloy or a titanium alloy. Since the components in the coating film and the workpiece are diffused to each other during the cutting so as to promote wear when Cr is contained in the coating film, the coating film preferably includes no Cr. In the cutting tool according to the first embodiment, the first layer does not include Cr, thereby suppressing the wear from being caused due to the components in the coating film and the workpiece including Cr being diffused to each other.

The first layer consists of the alternating layer in which the first unit layer and the second unit layer are alternately stacked. The composition and the crystal lattice are discontinuous at an interface between the first unit layer and the second unit layer. Therefore, when a crack is generated from the surface of the coating film during the cutting, progress of the crack can be suppressed at the interface. Chipping and breakage are suppressed in the coating film including the first layer.

Due to the above reasons, the cutting tool including the first layer consisting of the alternating layer in which the first unit layer and the second unit layer are alternately stacked can have an excellent tool life particularly even under such cutting conditions that the cutting edge temperature becomes high.

(2) In (1), in the first unit layer and the second unit layer adjacent to the first unit layer, a ratio λ2/λ1 of a thickness λ2 of the second unit layer to a thickness λ1 of the first unit layer may be 1 or more and 5 or less.

In addition to the high oxidation resistance, the second unit layer has a low heat conductivity and has a property to be less likely to transfer heat generated during the cutting to the substrate. When ratio λ2/λ1 is 1 or more and 5 or less, a ratio of the second unit layer in the first layer is increased, thereby further improving the adherence resistance, slidability, oxidation resistance and heat resistance of the first layer. Therefore, particularly even under such cutting conditions that the cutting edge temperature becomes high, the coating film is less likely to be worn, thereby further improving the tool life of the cutting tool.

Further, when λ2/λ1 is 1 or more, toughness of the coating film tends to be improved. On the other hand, when λ2/λ1 is 5 or less, the effect of suppressing the progress of the crack by stacking the first unit layer and the second unit layer tends to be readily obtained.

(3) In (1) or (2), an average thickness of the first unit layer may be 2 nm or more and 200 nm or less, and an average thickness of the second unit layer may be 2 nm or more and 200 nm or less. Thus, the effect of suppressing the progress of the crack generated in the surface of the coating film is further improved.

(4) In any one of (1) to (3), the coating film may further include a second layer disposed between the substrate and the first layer, a composition of the second layer may be the same as a composition of any of the first unit layer and the second unit layer, a thickness of the second layer may be larger than an average thickness of the unit layer having the same composition as the composition of the second layer, and the thickness of the second layer may be 0.1 μm or more and 1.0 μm or less. Thus, adhesion between the substrate and the coating film can be improved.

(5) In any one of (1) to (4), the coating film may further include a third layer provided on a side of the first layer opposite to the substrate, the third layer may consist of TiCN or TiAlScCN, and a thickness of the third layer may be 0.1 μm or more and 1.0 μm or less.

In general, a carbonitride tends to have a lower friction coefficient with respect to a workpiece than a nitride. Such a lower friction coefficient is considered to result from contribution of carbon atoms. When the coating film includes the third layer, the friction coefficient of the coating film with respect to the workpiece is decreased, with the result that the life of the cutting tool becomes longer.

(6) In any one of (1) to (5), a thickness of the first layer may be 0.5 μm or more and 15 μm or less. When the thickness of the first layer is 0.5 μm or more, the effect of improving the wear resistance, heat resistance, chipping resistance, adherence resistance, and the like of the first layer is facilitated to be obtained, with the result that the life of the cutting tool becomes longer. When the thickness of the first layer is 15 μm or less, the chipping resistance is likely to be stably exhibited.

(7) A cutting tool according to the present disclosure is a cutting tool comprising: a substrate; and a coating film disposed on the substrate, wherein the coating film includes an A layer, the A layer consists of an alternating layer in which a first unit layer and a third unit layer are alternately stacked, the first unit layer consists of Ti_{1-a-b}AlₐSc_{b}N, the a is 0.350 or more and 0.650 or less, the b is 0.010 or more and 0.100 or less, the third unit layer consists of Al_{c}V_{1-d-e}MₑN, the M is silicon or boron, the d is 0.40 or more and 0.75 or less, the e is more than 0 and 0.05 or less, and the a and the d satisfy a relation of d>a.

According to the present disclosure, it is possible to provide a cutting tool that can have an excellent tool life particularly even under such cutting conditions that a cutting edge temperature becomes high. This is presumably due to the same reasons as the reasons described above in (1). In the present disclosure, the following reasons are also presumed.

When the M is silicon in the Al_{d}V_{1-d-e}MₑN of the third unit layer, the structure of the third unit layer becomes fine to improve the hardness and oxidation resistance of the third unit layer, with the result that the hardness and oxidation resistance of the whole of the coating film are improved.

When the M is boron in the Al_{d}V_{1-d-e}MₑN of the third unit layer, the hardness of the third unit layer becomes high by the boron, with the result that the hardness of the whole of the coating film becomes high. Further, an oxide of the boron as formed by the cutting densifies the oxide of Al in the third unit layer, with the result that the oxidation resistance of the third unit layer is improved. Further, since the oxide of the boron has a low melting point, the oxide of the boron functions as a lubricant during the cutting, thereby suppressing adherence of the workpiece.

(8) In (7), in the first unit layer and the third unit layer adjacent to the first unit layer, a ratio λ3/λ1 of a thickness λ3 of the third unit layer to a thickness λ1 of the first unit layer may be 1 or more and 5 or less.

Thus, the adherence resistance, slidability, oxidation resistance, and heat resistance of the A layer are further improved due to the same reason as in (2), thereby further improving the tool life of the cutting tool.

(9) In (7) or (8), the M may be silicon. Thus, the hardness and oxidation resistance of the third unit layer are further improved, with the result that the hardness and oxidation resistance of the whole of the coating film are further improved.

(10) In (7) or (8), the M may be boron. Thus, the hardness and oxidation resistance of the third unit layer are further improved, with the result that the hardness and oxidation resistance of the whole of the coating film are further improved. Moreover, the adherence of the workpiece to the coating film can be further suppressed.

(11) In any one of (7) to (10), an average thickness of the first unit layer may be 2 nm or more and 200 nm or less, and an average thickness of the third unit layer may be 2 nm or more and 200 nm or less. Thus, the effect of suppressing the progress of the crack generated in the surface of the coating film is further improved.

(12) In any one of (7) to (11), the coating film may further include a B layer disposed between the substrate and the A layer, a composition of the B layer may be the same as a composition of any of the first unit layer and the third unit layer, a thickness of the B layer may be larger than an average thickness of the unit layer having the same composition as the composition of the B layer, and the thickness of the B layer may be 0.1 μm or more and 1 μm or less. Thus, adhesion between the substrate and the coating film can be improved.

(13) In any one of (7) to (12), the coating film may further include a C layer provided on a side of the A layer opposite to the substrate, the C layer may consist of TiCN or TiAlScCN, and a thickness of the C layer may be 0.1 μm or more and 1.0 μm or less. Thus, the friction coefficient of the coating film with respect to the workpiece is decreased, with the result that the life of the cutting tool becomes longer.

(14) In any one of (7) to (13), a thickness of the A layer may be 0.5 μm or more and 15 μm or less. When the thickness of the A layer is 0.5 μm or more, the effect of improving the wear resistance, heat resistance, chipping resistance, adherence resistance, and the like of the A layer is facilitated to be obtained, with the result that the life of the cutting tool becomes longer. When the thickness of the A layer is 15 μm or less, the chipping resistance is likely to be stably exhibited.

### DETAILS OF EMBODIMENTS OF THE PRESENT DISCLOSURE

A specific example of the cutting tool of the present disclosure will be described below with reference to figures. In the figures of the present disclosure, the same reference characters represent the same or corresponding portions. Further, a dimensional relation such as a length, a width, a thickness, or a depth is appropriately changed for clarity and simplification of the figures, and therefore do not necessarily represent an actual dimensional relation.

In the present disclosure, the expression “A to B” means A or more and B or less, and when no unit is indicated for A and a unit is indicated only for B, the unit of A is the same as the unit of B.

When a compound or the like is expressed by a chemical formula in the present disclosure and an atomic ratio is not particularly limited, it is assumed that all the conventionally known atomic ratios are included, and the atomic ratio should not be necessarily limited only to one in the stoichiometric range.

In the present disclosure, when one or more numerical values are described as each of lower and upper limits of a numerical range, it is assumed that a combination of any one numerical value described as the lower limit and any one numerical value described as the upper limit is also disclosed.

In the present disclosure, the terms “comprise”, “include”, “have”, and variations thereof are open-ended terms. Each of the open-ended terms may or may not further include an additional element in addition to an essential element. The description “consist of” is a closed term. It should be noted that even a configuration expressed by such a closed term can include an impurity introduced in an ordinary case or an additional element irrelevant to the target technology.

### First Embodiment: Cutting Tool (1)

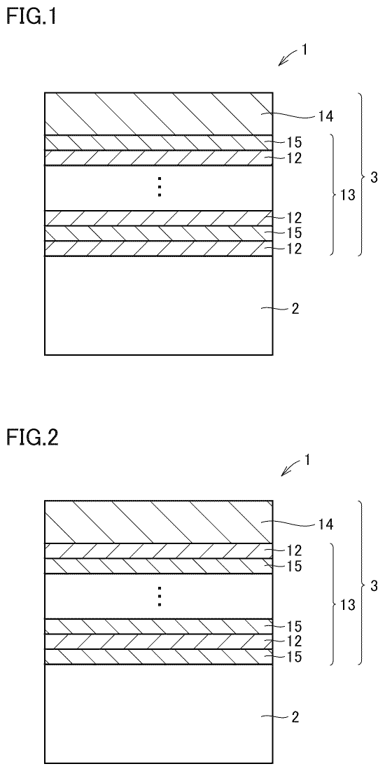

A cutting tool according to one embodiment (hereinafter, also be referred to as “first embodiment”) of the present disclosure will be described with reference to FIGS. 1 to 5. A cutting tool 1 according to the first embodiment is a cutting tool 1 including a substrate 2 and a coating film 3 disposed on substrate 2. Coating film 3 includes a first layer 13. First layer 13 consists of an alternating layer in which first unit layers 12 and second unit layers 15 are alternately stacked. First unit layer 12 consists of Ti_{1-a-b}AlₐSc_{b}N. Here, the a is 0.350 or more and 0.650 or less, and the b is 0.010 or more and 0.100 or less. Second unit layer 15 consists of Al_{c}V_{1-c}N. Here, the c is 0.40 or more and 0.75 or less. The a and the c satisfy a relation of c>a.

### <<Cutting Tool>>

The cutting tool according to the first embodiment can be suitably used as a drill, an end mill, an indexable cutting insert for drill, an indexable cutting insert for end mill, an indexable cutting insert for milling, an indexable cutting insert for turning, a metal saw, a gear cutting tool, a reamer, a tap, or the like.

### <Substrate>

As the composition of the substrate, any conventionally known composition can be used. For example, any one of a cemented carbide (such as a WC-based cemented carbide, a cemented carbide including WC and Co, or a cemented carbide to which a carbonitride of Ti, Ta, Nb or the like is further added), a cermet (having TiC, TiN, TiCN, or the like as a main component), a high-speed steel, a ceramic (such as titanium carbide, silicon carbide, silicon nitride, aluminum nitride, or aluminum oxide), a cubic boron nitride sintered material, or a diamond sintered material can be used.

The composition of the substrate may be the WC-based cemented carbide or the cermet (particularly, the TiCN-based cermet) from the viewpoint of excellent balance between hardness and strength at a high temperature. The substrate consisting of such a WC-based cemented carbide or cermet can contribute to a long life of the cutting tool.

### <Coating Film>

In the cutting tool according to the first embodiment, the coating film can coat at least a portion of the substrate involved in cutting. The portion of the substrate involved in cutting means, for example, a region at a distance of 100 μm or less from a cutting edge ridgeline in a surface of the substrate. The coating film may coat the entire surface of the substrate, or may coat the entire surface of the portion of the substrate involved in cutting. As long as the effects of the cutting tool of the present disclosure are not impaired, a configuration in which the coating film is not formed on a part of the portion of the substrate involved in the cutting is not deviated from the scope of the first embodiment. As long as the effects of the cutting tool of the present disclosure are not impaired, a partially different configuration of the coating film is not deviated from the scope of the first embodiment.

As shown in FIGS. 1 and 2, coating film 3 may include first layer 13, and first layer 13 may be provided directly on substrate 2.

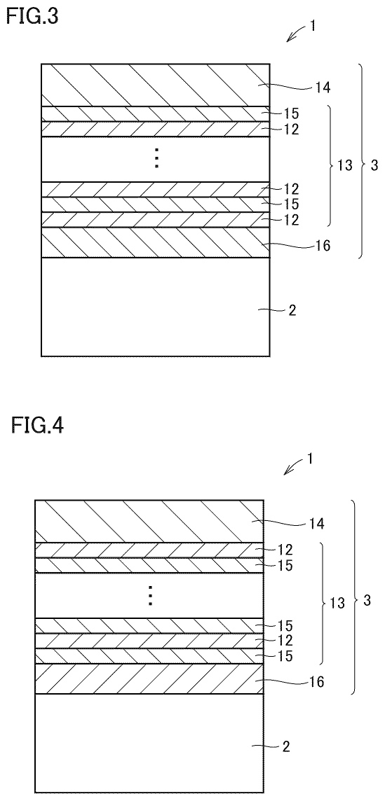

Coating film 3 can include another layer in addition to first layer 13. As shown in FIGS. 3 and 4, coating film 3 may include a second layer 16 disposed between substrate 2 and first layer 13. As shown in FIGS. 1 to 4, coating film 3 may include a third layer 14 provided on a side of first layer 13 opposite to substrate 2.

The thickness of the coating film may be 0.5 μm or more and 25 μm or less, may be 1.0 μm or more and 23 μm or less, or may be 5.0 μm or more and 20 μm or less.

The thickness of the coating film is measured by observing a cross section of the coating film using a SEM (scanning electron microscope). Specifically, a cross sectional sample is observed for an observation area of 100 to 500 μm² at an observation magnification of 5000 to 10000 times so as to measure thicknesses at three locations in one visual field, and the average value thereof is defined as the thickness of the coating film. The thickness of each of below-described layers is also measured in the same manner unless otherwise stated particularly.

The compressive residual stress of the coating film may have an absolute value of 6 GPa or less. The compressive residual stress of the coating film is a type of internal stress (inherent strain) existing in the whole of the coating film, and is a stress expressed by a numerical value with an indication of “−” (minus) (unit: “GPa” is used in the present embodiment). Therefore, a concept that the compressive residual stress is large indicates that the absolute value of the numerical value is large, whereas a concept that the compressive residual stress is small indicates that the absolute value of the numerical value is small. That is, the expression “the absolute value of the compressive residual stress is 6 GPa or less” means that a preferable compressive residual stress for the coating film is −6 GPa or more and 0 GPa or less.

When the compressive residual stress of the coating film becomes more than 0 GPa, the compressive residual stress becomes tensile stress, with the result that progress of a generated crack from the outermost surface of the coating film tends to be less likely to be suppressed. On the other hand, when the absolute value of the compressive residual stress becomes more than 6 GPa, the stress is too large and the coating film may be accordingly detached particularly from an edge portion of the cutting tool before starting the cutting, with the result that the life of the cutting tool may become short.

The compressive residual stress of the coating film can be measured by a sin 2ψ method (see pages 54 to 66 of “X-ray stress measurement method” (The Society of Materials Science, Japan, 1981, published by YOKENDO)) using an X-ray residual stress apparatus.

The crystal structure of the coating film may be a cubic crystal structure. When the crystal structure of the coating film is the cubic crystal structure, the hardness of the coating film is improved. The crystal structure of each of the layers in the coating film may be the cubic crystal structure. It should be noted that the crystal structure of the coating film and the crystal structure of each of the layers in the coating film can be analyzed by an X-ray diffractometer known in the field of art.

The hardness of the coating film may be 30 GPa or more and 55 GPa or less, or may be 35 GPa or more and 50 GPa or less. Thus, the coating film has a sufficient hardness. The hardness of the whole of the coating film can be measured in accordance with a nano indenter method (Nano Indenter XP provided by MTS). Specifically, the measurement was performed in accordance with a method compliant with ISO14577 so as to measure hardnesses at three locations on the surface of the coating film with a measurement load being set to 10 mN (1 gf), and the average value thereof is defined as “hardness”.

### <First Layer>

In the cutting tool according to the first embodiment, the first layer consists of the alternating layer in which the first unit layers and the second unit layers are alternately stacked. From a difference in contrast when a thin piece sample including a cross section of the coating film is observed with a TEM (transmission electron microscope), it can be confirmed that the first layer consists of the alternating layer in which the first unit layers and the second unit layers are alternately stacked.

Any of a first unit layer and a second unit layer may be disposed at a position closest to the substrate side. Any of first unit layer 12 and second unit layer 15 may be disposed at a position closest to the surface side of coating film 3.

The thickness of the first layer may be 0.5 μm or more and 15 μm or less, 2 μm or more and 15 μm or less, or 5 μm or more and 10 μm or less.

The thickness of the first layer can be measured by observing a cross section of the coating film using the transmission electron microscope (TEM). The cutting tool is cut in a direction along a line normal to the surface of the coating film so as to prepare a thin piece sample including the cross section. The thin piece sample is observed with the TEM. An observation magnification is set to 20000 to 5000000 times, and a measurement visual field is set to 0.0016 to 80 μm². In one visual field, thicknesses at three locations of the first layer are measured, and the average value of the thicknesses at the three locations is defined as the thickness of the first layer.

### <Composition of First Unit Layer and Composition of Second Unit Layer>

The first unit layer consists of Ti_{1-a-b}AlₐSc_{b}N, the a is 0.350 or more and 0.650 or less, and the b is 0.010 or more and 0.100 or less.

The a is 0.350 or more and 0.650 or less, may be 0.400 or more and 0.600 or less, or may be 0.450 or more and 0.550 or less.

The b is 0.010 or more and 0.100 or less, may be 0.020 or more and 0.090 or less, may be 0.030 or more and 0.080 or less, or may be 0.040 or more and 0.070 or less.

In the present disclosure, the expression “the first unit layer consists of Ti_{1-a-b}AlₐSc_{b}N” means that the first unit layer can include an inevitable impurity in addition to Ti_{1-a-b}AlₐSc_{b}N as long as the effects of the present disclosure are not impaired. Examples of the inevitable impurity include oxygen, argon, and carbon. The content ratio of the whole of the inevitable impurity in the first unit layer may be more than 0 atomic % and less than 1 atomic %.

Each of the a and the b is found by measuring the energy and the number of times of generation of characteristic X-rays when an electron beam is applied on the cross section of the thin piece of the coating film using an energy dispersive X-ray spectrometer (EDX) accompanied with the transmission electron microscope (TEM), and performing an elemental analysis. The below-described c in Al_{c}Cr_{1-c}N and d and e in Al_{d}Cr_{1-d-e}MₑN are also measured in the same manner.

The second unit layer consists of Al_{c}V_{1-c}N, and the c is 0.40 or more and 0.75 or less. The c may be 0.45 or more and 0.70 or less, 0.50 or more and 0.65 or less, or 0.55 or more and 0.60 or less.

In the present disclosure, the expression “the second unit layer consists of Al_{c}V_{1-c}N” means that the second unit layer can include an inevitable impurity in addition to the Al_{c}V_{1-c}N, as long as the effects of the present disclosure are not impaired. Examples of the inevitable impurity include oxygen and carbon. The content ratio of the whole of the inevitable impurity in the second unit layer may be more than 0 atomic % and less than 1 atomic %.

The a and the c satisfy the relation of c>a. Thus, the content ratio of Al in the first layer is likely to be large, with the result that the heat resistance and oxidation resistance of the first layer are likely to be improved.

In the present disclosure, in the composition, Ti_{1-a-b}AlₐSc_{b}N, of the first unit layer, a ratio A_{N1}/A_{M1} of the number of atoms A_{N1} of N to the total number of atoms A_{M1} of Ti, Al, and Sc is 0.8 or more and 1.2 or less. In the present disclosure, in the composition, Al_{c}V_{1-c}N, of the second unit layer, a ratio A_{N2}/A_{M2} of the number of atoms A_{N2} of N to the total number of atoms A_{M2} of Al and V is 0.8 or more and 1.2 or less. Each of ratio A_{N1}/A_{M1} and ratio A_{N2}/A_{M2} can be measured by the Rutherford backscattering spectrometry (RBS). It has been confirmed that the effects of the present disclosure are not impaired when ratio A_{N1}/A_{M1} and ratio A_{N2}/A_{M2} are in the above respective ranges.

### <Average Thickness of First Unit Layers and Average Thickness of Second Unit Layers>

The average thickness of the first unit layers may be 2 nm or more and 200 nm or less, and the average thickness of the second unit layers may be 2 nm or more and 200 nm or less. The average thickness of the first unit layers may be 5 nm or more and 150 nm or less, or may be 10 nm or more and 100 nm or less. The average thickness of the second unit layers may be 5 nm or more and 150 nm or less, or may be 10 nm or more and 100 nm or less.

Each of the average thickness of the first unit layers and the average thickness of the second unit layers is measured in the same manner as in the method of measuring the thickness of the first layer.

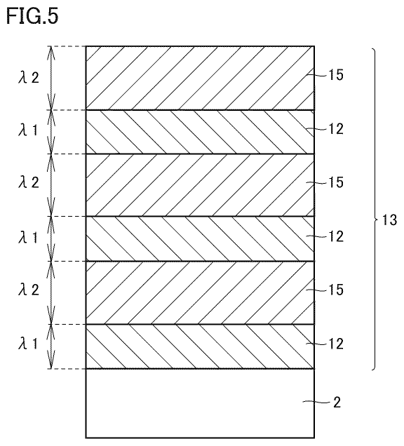

As shown in FIG. 5, in first unit layer 12 and second unit layer 15 adjacent to first unit layer 12, a ratio λ2/λ1 of thickness λ2 (nm) of second unit layer 15 to thickness λ1 (nm) of first unit layer 12 may be 1 or more and 5 or less, may be 1.1 or more and 5.0 or less, may be 1.2 or more and 5.0 or less, may be 1.3 or more and 4.0 or less, may be 1.8 or more and 3.0 or less, or may be 2.0 or more and 2.5 or less.

Although the thickness of each of all the first unit layers 12 is denoted by λ1 and the thickness of each of all the second unit layers 15 is denoted by λ2 for the sake of explanation in FIG. 5, thicknesses λ1 of all the first unit layers 12 does not need to be the same and thicknesses 22 of all the second unit layers 15 does not need to be the same as long as the relation of λ2/λ1 is satisfied between the first unit layer and the second unit layer adjacent to each other.

In the first layer, each of the number of the first unit layers stacked and the number of the second unit layers stacked may be 5 or more and 500 or less, may be 10 or more and 500 or less, may be 100 or more and 400 or less, or may be 200 or more and 350 or less. Thus, by stacking the first unit layers and the second unit layers, it is possible to sufficiently obtain the effect of improving the hardness, wear resistance, heat resistance, chipping resistance, and adherence resistance of the first layer in a well-balanced manner.

In the first layer, each of the number of the first unit layers stacked and the number of the second unit layers stacked is measured by observing the thin piece sample of the cross section of the coating film using the TEM (transmission electron microscope) at an observation magnification of 20000 to 5000000 times. Each of the number of first unit layers stacked and the number of third unit layers stacked in a below-described A layer is also measured in the same manner.

### <Second Layer>

In the cutting tool according to the first embodiment, the coating film may further include a second layer disposed between the substrate and the first layer. The composition of the second layer may be the same as the composition of any of each of the first unit layers and each of the second unit layers. The second layer may be disposed directly on the substrate.

In the case where the composition of the second layer is the same as the composition of the first unit layer, even when the second layer is exposed at an initial stage of cutting, a passivation consisting of Sc₂O₃ is generated, thereby improving the stability of the performance of the cutting tool. Further, oxidation of the coating film can be suppressed by the keying on effect of Sc₂O₃. Further, due to the keying on effect, reactivity between the workpiece and the coating film can be suppressed, thereby reducing a friction coefficient between the workpiece and the coating film.

When the composition of the second layer is the same as the composition of the first unit layer, the thickness of the second layer may be larger than the thickness of the first unit layer. This leads to further improvement of the stability of the performance of the cutting tool due to the formation of Sc₂O₃, further improvement of the effect of suppressing the oxidation of the coating film, and further improvement of the effect of suppressing the reactivity between the workpiece and the coating film. Moreover, the friction coefficient between the workpiece and the coating film can be further reduced.

When the composition of the second layer is the same as the composition of the first unit layer, first unit layer 12 may be stacked directly on second layer 16 as shown in FIG. 3. Moreover, second unit layer 15 may be stacked directly on second layer 16 as shown in FIG. 4. When the composition of the second layer is the same as the composition of the first unit layer and the first unit layer is stacked directly on the second layer, the second layer and the first unit layer have continuous crystal structures.

When the composition of the second layer is the same as the composition of the second unit layer, V₂O₅ is generated even when the second layer is exposed at the initial stage of cutting. Thus, progress of the oxidation of the coating film can be suppressed. Further, the second layer can suppress oxidation from the interface between the substrate and the coating film and can block cutting heat.

When the composition of the second layer is the same as the composition of the second unit layer, the thickness of the second layer may be thicker than the thickness of the second unit layer. Thus, the suppression of the progress of the oxidation of the coating film and the effect of blocking cutting heat are further improved.

The thickness of the second layer may be more than 1 time and 500 times or less, may be 2 times or more and 500 times or less, may be 4 times or more and 120 times or less, or may be 10 times or more and 50 times or less as large as the thickness of the unit layer having the same composition as that of the second layer.

The thickness of the second layer may be 0.1 μm or more and 2 μm or less, may be 0.3 μm or more and 2 μm or less, or may be 0.4 μm or more and 1 μm or less. Thus, the above-described effect by disposing the second layer is facilitated to be obtained.

When the composition of the second layer is the same as the composition of the second unit layer, first unit layer 12 may be stacked directly on second layer 16 as shown in FIG. 3. Moreover, second unit layer 15 may be stacked directly on second layer 16 as shown in FIG. 4. When the composition of the second layer is the same as the composition of the second unit layer and the second unit layer is stacked directly on the second layer, the second layer and the second unit layer have continuous crystal structures.

### <Third Layer>

In the cutting tool according to the first embodiment, the coating film may further include the third layer provided on a side of the first layer opposite to the substrate. The third layer may be disposed on the outermost surface of the coating film. The third layer may consist of TiCN or TiAlScCN.

When the third layer consists of TiCN, a predetermined color can be given by adjusting the composition ratio of N and C. Thus, the external appearance of the cutting tool can be provided with a design property and distinguishability, which is commercially advantageous.

When the third layer consists of TiAlScCN, a passivation consisting of Sc₂O₃ is generated under high-temperature cutting conditions, thereby improving the stability of the performance of the cutting tool.

When the third layer consists of TiAlScCN, the atomic ratio of Ti, Al, and Sc in the third layer may be the same as the atomic ratio of Ti, Al, and Sc in the first unit layer. Specifically, when the atomic ratio of Ti, Al and Sc in the first unit layer is Ti:Al:Sc=1−a−b:a:b, the atomic ratio of Ti, Al and Sc in the third layer may also be Ti:Al:Sc=1−a−b:a:b. Thus, when the coating film is produced by a PVD method, the first unit layer and the third layer can be produced using the same target, which is advantageous in terms of cost.

The thickness of the third layer may be 0.1 μm or more and 1.0 μm or less. When the thickness of the third layer is 0.1 μm or more, the above-described effect by disposing the third layer is excellent. In consideration of the cost, the thickness of the third layer may be 1.0 μm or less. The thickness of the third layer may be 0.3 μm or more and 0.8 μm or less, or may be 0.5 μm or more and 0.6 μm or less.

### Second Embodiment: Cutting Tool (2)

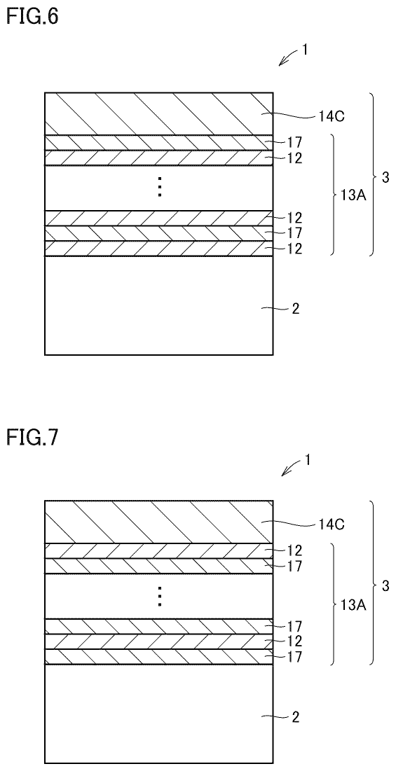

A cutting tool according to another embodiment of the present disclosure will be described with reference to FIGS. 6 to 10. A cutting tool according to a second embodiment is a cutting tool including a substrate and a coating film disposed on the substrate. The coating film includes an A layer. The A layer consists of an alternating layer in which first unit layers and third unit layers are alternately stacked. Each of the first unit layers consists of Ti_{1-a-b}AlₐSc_{b}N. Here, the a is 0.350 or more and 0.650 or less, and the b is 0.010 or more and 0.100 or less. Each of the third unit layers consists of Al_{d}V_{1-d-e}MₑN. Here, the M is silicon or boron, the d is 0.40 or more and 0.75 or less, and the e is more than 0 and 0.05 or less. The a and the d satisfy a relation of d>a.

The cutting tool according to the second embodiment can basically have the same configuration as that of the cutting tool according to the first embodiment except for the configurations of the A layer, a B layer, and a C layer. Hereinafter, a difference from the cutting tool according to the first embodiment will be described.

### <Coating Film>

As shown in FIGS. 6 and 7, a coating film 3 may include an A layer 13A, and A layer 13A may be provided directly on a substrate 2.

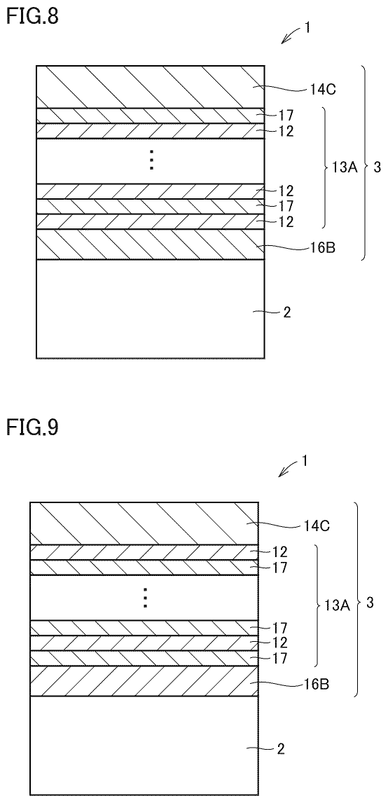

Coating film 3 can include another layer in addition to A layer 13A. As shown in FIGS. 8 to 9, coating film 3 may include a B layer 16B disposed between substrate 2 and A layer 13A. As shown in FIGS. 6 to 9, coating film 3 may include a C layer 14C provided on a side of A layer 13A opposite to substrate 2.

### <A Layer>

In the cutting tool according to the second embodiment, the A layer consists of the alternating layer in which the first unit layers and the third unit layers are alternately stacked. The thickness of the A layer can be the same as the thickness of the first layer described in the first embodiment. Any of a first unit layer and a third unit layer may be disposed at a position closest to the substrate side. The first unit layer can have a cubic crystal structure. The third unit layer can have a cubic crystal structure.

### <Composition of First Unit Layer and Composition of Third Unit Layer>

The composition, Ti_{1-a-b}AlₐSc_{b}N, of the first unit layer of the second embodiment can be the same as the composition, Ti_{1-a-b}AlₐSc_{b}N, of the first unit layer of the first embodiment.

The third unit layer consists of Al_{d}V_{1-d-e}MₑN, the M is silicon or boron, the d is 0.40 or more and 0.75 or less, and the e is more than 0 and 0.05 or less.

The d is 0.40 or more and 0.75 or less. Thus, the crystal structure of the third unit layer becomes a cubic crystal structure, the hardness of the third unit layer becomes high, and the wear resistance is improved. The d may be 0.45 or more and 0.70 or less, may be 0.50 or more and 0.65 or less, or may be 0.55 or more and 0.60 or less.

The e is more than 0 and 0.05 or less. Thus, the hardness and oxidation resistance of the A layer can be improved.

In the present disclosure, the expression “the third unit layer consists of Al_{d}V_{1-d-e}MₑN” means that the third unit layer can include an inevitable impurity in addition to Al_{d}V_{1-d-e}MₑN as long as the effects of the present disclosure are not impaired. Examples of the inevitable impurity include oxygen and carbon. The content of the whole of the inevitable impurity in the third unit layer may be more than 0 atomic % and less than 1 atomic %.

The a and the d satisfy the relation of d>a. Thus, the content ratio of Al in the first layer is likely to be large, with the result that the heat resistance and oxidation resistance of the first layer are likely to be improved.

In the present disclosure, in the composition, Al_{d}V_{1-d-e}MₑN, of the third unit layer, a ratio A_{N3}/A_{M3} of the number of atoms A_{N3} of N to the total number of atoms A_{M3} of Al, V, and M is 0.8 or more and 1.2 or less. Ratio A_{N3}/A_{M3} can be measured by the Rutherford backscattering spectrometry (RBS). It has been confirmed that the effects of the present disclosure are not impaired when ratio A_{N1}/A_{M1} is 0.8 or more and 1.2 or less and ratio A_{N3}/A_{M3} is in the above range.

### <Average Thickness of First Unit Layers and Average Thickness of Third Unit Layers>

The average thickness of the first unit layers may be 2 nm or more and 200 nm or less, and the average thickness of the third unit layers may be 2 nm or more and 200 nm or less. The average thickness of the first unit layers may be 5 nm or more and 150 nm or less, or may be 10 nm or more and 100 nm or less. The average thickness of the third unit layers may be 5 nm or more and 150 nm or less, or may be 10 nm or more and 100 nm or less.

Each of the average thickness of the first unit layers and the average thickness of the third unit layers is measured in the same manner as in the method of measuring the thickness of the first layer.

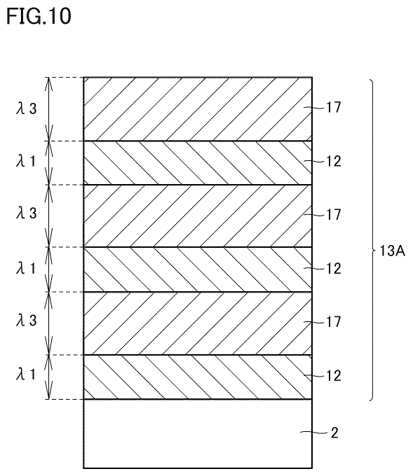

As shown in FIG. 10, in first unit layer 12 and third unit layer 17 adjacent to first unit layer 12, a ratio λ3/λ1 of thickness λ3 (nm) of third unit layer 17 to thickness λ1 (nm) of first unit layer 12 may be 1 or more and 5 or less, may be 1.1 or more and 5.0 or less, may be 1.2 or more and 5.0 or less, may be 1.3 or more and 4.0 or less, may be 1.8 or more and 3.0 or less, or may be 2.0 or more and 2.5 or less.

Although the thickness of each of all the first unit layers 12 is denoted by λ1 and the thickness of each of all the third unit layers 17 is denoted by λ3 for the sake of explanation in FIG. 10, thicknesses λ1 of all the first unit layers 12 do not need to be the same and thicknesses λ3 of all the third unit layers 17 do not need to be the same as long as the relation of λ3/λ1 is satisfied between the first unit layer and the third unit layer adjacent to each other.

In the A layer, each of the number of the first unit layers stacked and the number of the third unit layers stacked may be 5 or more and 500 or less, may be 10 or more and 500 or less, may be 100 or more and 400 or less, or may be 200 or more and 350 or less. Thus, by stacking the first unit layers and the third unit layers, it is possible to sufficiently obtain the effect of improving the hardness, wear resistance, heat resistance, chipping resistance, and adherence resistance of the A layer in a well-balanced manner.

### <B Layer>

In the cutting tool according to the second embodiment, the coating film may further include the B layer disposed between the substrate and the A layer. The composition of the B layer may be the same as the composition of any of each of the first unit layers and each of the third unit layers. The B layer may be disposed directly on the substrate.

The effect and the thickness of the B layer when the composition of the B layer is the same as the composition of the first unit layer are as described in the first embodiment.

When the composition of the B layer is the same as the composition of the third unit layer, the stress of the third unit layer tends to be small and therefore detachment resistance of the coating film can be improved particularly in intermittent processing, such as milling or end milling, in which a load is repeatedly applied to the cutting edge.

When the composition of the B layer is the same as the composition of the third unit layer, the thickness of the B layer may be thicker than the thickness of the third unit layer. Thus, the suppression of progress of oxidation of the coating film and the effect of blocking cutting heat can be further improved.

The thickness of the B layer may be more than 1 time and 500 times or less, may be 2 times or more and 500 times or less, may be 4 times or more and 120 times or less, or may be 10 times or more and 50 times or less as large as the thickness of the unit layer having the same composition as that of the B layer.

The thickness of the B layer may be 0.1 μm or more and 2 μm or less, may be 0.3 μm or more and 2 μm or less, or may be 0.4 μm or more and 1 μm or less. Thus, the above-described effect by disposing the B layer is facilitated to be obtained.

When the composition of the B layer is the same as the composition of the third unit layer, first unit layer 12 may be stacked directly on B layer 16B as shown in FIG. 8. Moreover, third unit layer 17 may be stacked directly on B layer 16B as shown in FIG. 9. When the composition of the B layer is the same as the composition of the third unit layer and the third unit layer is stacked directly on the B layer, the B layer and the third unit layer have continuous crystal structures.

### <C Layer>

The C layer can have the same configuration and effect as those of the third layer described in the first embodiment.

### Third Embodiment: Method of Manufacturing Cutting Tool

In a third embodiment, a method of manufacturing the cutting tool according to the first embodiment or the second embodiment will be described. The method of manufacturing the cutting tool according to the third embodiment includes: a first step of preparing the substrate; and a second step of forming the coating film on the substrate. The second step includes a step of forming the first layer or the A layer. Details of each step will be described below.

### <First Step>

In the first step, the substrate is prepared. As the substrate, the substrate described in the first embodiment can be used. Any conventionally known substrate can be prepared.

### <Second Step>

In the second step, the coating film is formed on the substrate. The second step includes the step of forming the first layer or the A layer.

In the step of forming the first layer, the first layer is formed by alternately stacking the first unit layers and the second unit layers using a physical vapor deposition (PVD) method. In the step of forming the A layer, the A layer is formed by alternately stacking the first unit layers and the third unit layers using the PVD method. In order to improve the wear resistance of the coating film including the first layer or the A layer, it is effective to form a layer consisting of a compound having high crystallinity. The present inventors have found that the layer consisting of the compound having high crystallinity can be formed by using the physical vapor deposition method as the method of forming the first layer and the A layer, and the coating film has excellent wear resistance.

As the PVD method, at least one selected from a group consisting of a cathode arc ion plating method, a balanced magnetron sputtering method, an unbalanced magnetron sputtering method, and a HiPIMS (High Power Impulse Magnetron Sputtering) method can be used. The cathode arc ion plating method, which allows for a high ionization ratio of a source material element, may be used. In the case of using the cathode arc ion plating method, since ion bombardment treatment for metal can be performed onto the surface of the substrate before the first layer or the A layer is formed, adhesion between the substrate and the coating film including the first layer or the A layer is significantly improved.

The cathode arc ion plating method can be performed by: placing the substrate in an apparatus and placing a target as a cathode; and then applying high voltage to the target to generate arc discharge so as to ionize and evaporate atoms that constitute the target; and depositing a substance on the substrate, for example.

The balanced magnetron sputtering method can be performed by: placing the substrate in an apparatus and placing a target on a magnetron electrode that has a magnet to form a balanced magnetic field; applying high-frequency electric power between the magnetron electrode and the substrate to generate gas plasma; allowing gas ions generated by the generation of this gas plasma to collide with the target; and depositing atoms released from the target on the substrate, for example.

The unbalanced magnetron sputtering method can be performed by setting the magnetic field, which is to be generated by the magnetron electrode, to be unbalanced in the above-described balanced magnetron spattering method, for example. The HiPIMS method, by which higher voltage can be applied to obtain a dense film, can also be used.

### <Other Steps>

The second step can include, in addition to the step of forming the first layer or the A layer, a surface treatment step for the coating film, such as polishing using a brush or dry type or wet type shot blasting. Moreover, the second step can include a step of forming other layers such as the second layer, the third layer, the B layer, and the C layer. Each of the other layers can be formed by a conventionally known chemical vapor deposition method or physical vapor deposition method. The other layer is preferably formed by the physical vapor deposition method from such a viewpoint that the other layer can be formed to be continuous to the first layer or the A layer in one physical vapor deposition apparatus.

### EXAMPLES

The present embodiment will be described more specifically with reference to examples. It should be noted that the present embodiment is not limited by these examples.

### Example 1

### <Samples 1 to 18 and Samples 101 to 109>

### <<Production of Cutting Tool>>

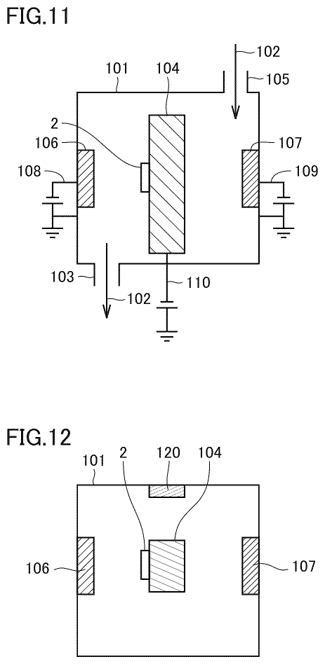

FIG. 11 is a schematic cross sectional view of a cathode arc ion plating apparatus used in an Example 1, and FIG. 12 is a schematic top view of the apparatus of FIG. 11.

In the apparatus shown in FIGS. 11 and 12, a cathode 106 for a first unit layer, a cathode 107 for a second unit layer, and a cathode 120 for a third layer, each of which is a target composed of an alloy and serving as a metal source material for a coating film, and a rotary type substrate holder 104 for placing a substrate are attached in a chamber 101. Cathode 106 consists of Ti, Al, and Sc, and a ratio of the respective elements is adjusted so as to obtain the composition of the first unit layer in Table 1. Cathode 107 consists of Al and V, and a ratio of the respective elements is adjusted so as to obtain the composition of the second unit layer in Table 1. Cathode 120 consists of Ti.

An arc power supply 108 is attached to cathode 106, an arc power supply 109 is attached to cathode 107, and an arc power supply (not shown) is attached to cathode 120. Moreover, a bias power supply 110 is attached to substrate holder 104. Moreover, a gas introduction port 105 into which gas 102 is to be introduced, and a gas discharging port 103 for adjusting pressure in chamber 101 are provided in chamber 101, thereby attaining a structure in which gas 102 in chamber 101 can be suctioned via gas discharging port 103 by a vacuum pump.

A chip, which is a cemented carbide having a grade of K20 of the JIS standards and having a shape of CNMG120408 of the JIS standards, was attached on substrate holder 104 as a substrate.

Next, the pressure in chamber 101 was reduced by the vacuum pump, heating was performed to a temperature of 600° C. by a heater installed in the apparatus while rotating the substrate, and vacuuming was performed until the pressure in chamber 101 became 1.0×10⁻⁴ Pa. Next, argon gas was introduced from the gas introduction port to maintain the pressure in chamber 101 at 2.0 Pa, and voltage of bias power supply 110 was gradually increased to −1000 V, and the surface of the substrate was cleaned for 15 minutes. Thereafter, the substrate was cleaned by releasing the argon gas from the inside of chamber 101 (argon bombardment treatment). In this way, the substrate of the cutting tool of each sample was prepared.

Next, while nitrogen was introduced as a reaction gas with the substrate being rotated at the center, an arc current of 120 A was supplied to each of cathodes 106, 107 with the temperature of the substrate being maintained at 600° C., the pressure of the reaction gas being maintained at 2.0 Pa, and the voltage of bias power supply 110 being maintained at a predetermined certain value in a range of −50 V to −200 V, with the result that metal ions were generated from cathodes 106, 107 so as to form the second layer having a composition shown in Table 2 and the first layer having a composition shown in Table 1 on the substrate.

When the second layer was formed, the first layer was formed in such a manner that the respective numbers of the first unit layers and the second unit layers as shown in Table 1 are alternately stacked one by one on the second layer. When the second layer was not formed, the first layer was formed in such a manner that the respective numbers of the first unit layers and the second unit layers as shown in Table 1 are alternately stacked one by one on the substrate.

The thickness of the second layer, the thickness of each of the first unit layers and the second unit layers in the first layer, the number of the first unit layers stacked, and the number of the second unit layers stacked were adjusted by the rotation speed of the substrate. When the thicknesses of the second layer and the first layer became the thicknesses shown in Tables 1 and 2, the current supplied to the evaporation source was stopped. The description “-” in the column “Second Layer” of Table 2 indicates that the second layer is not present.

Next, while introducing each of nitrogen gas and methane gas into chamber 101 as a reaction gas, an arc current of 100 A was supplied to cathode 120 with the temperature of the substrate being maintained at 400° C., the reaction gas pressure being maintained at 2.0 Pa, and the voltage of bias power supply 110 being maintained at-300 V, thereby generating metal ions from cathode 120 to form a third layer on the first layer. When the thickness of the third layer became the thickness shown in Table 2, the current supplied to the evaporation source was stopped. In this way, the cutting tool of each sample was produced. The description “-” in the column “Third Layer” of Table 2 indicates that the third layer is not present.

TABLE 1

| | First Layer | | | | | | | | |
|---|---|---|---|---|---|---|---|---|---|
| | First Unit Layer | | | Second Unit Layer | | | | | |
| | (Ti_{1-a-b}AlₐSc_{b}N) | | | (Al_{c}V_{1-c}N) | | | | | |
| | | | Average | | Average | | | Number of | |
| Sample | | | Thickness | | Thickness | | | Stacked | Thickness |
| No. | a | b | [nm] | c | [nm] | c − a | λ2/λ1 | Layers | [μm] |
| 1 | 0.350 | 0.010 | 10 | 0.40 | 11 | 0.050 | 1.1 | 24 | 0.5 |
| 2 | 0.350 | 0.050 | 2 | 0.45 | 2 | 0.100 | 1.0 | 500 | 2.0 |
| 3 | 0.350 | 0.100 | 50 | 0.50 | 60 | 0.150 | 1.2 | 200 | 22.0 |
| 4 | 0.500 | 0.050 | 100 | 0.55 | 150 | 0.050 | 1.5 | 60 | 15.0 |
| 5 | 0.650 | 0.010 | 30 | 0.70 | 90 | 0.050 | 3.0 | 13 | 1.6 |
| 6 | 0.650 | 0.050 | 5 | 0.75 | 20 | 0.100 | 4.0 | 40 | 1.0 |
| 7 | 0.650 | 0.100 | 30 | 0.75 | 150 | 0.100 | 5.0 | 75 | 13.5 |
| 8 | 0.400 | 0.020 | 5 | 0.70 | 20 | 0.300 | 4.0 | 500 | 12.5 |
| 9 | 0.450 | 0.030 | 200 | 0.65 | 200 | 0.200 | 1.0 | 10 | 4.0 |
| 10 | 0.500 | 0.040 | 5 | 0.55 | 4 | 0.050 | 0.8 | 100 | 0.9 |
| 11 | 0.350 | 0.070 | 30 | 0.40 | 150 | 0.050 | 5.0 | 18 | 3.2 |
| 12 | 0.400 | 0.080 | 5 | 0.65 | 30 | 0.250 | 6.0 | 90 | 3.2 |
| 13 | 0.500 | 0.100 | 250 | 0.60 | 250 | 0.100 | 1.0 | 10 | 5.0 |
| 14 | 0.350 | 0.050 | 2 | 0.45 | 2 | 0.100 | 1.0 | 500 | 2.0 |
| 15 | 0.350 | 0.100 | 50 | 0.50 | 60 | 0.150 | 1.2 | 200 | 22.0 |
| 16 | 0.500 | 0.050 | 100 | 0.55 | 150 | 0.050 | 1.5 | 60 | 15.0 |
| 17 | 0.650 | 0.010 | 30 | 0.70 | 90 | 0.050 | 3.0 | 13 | 1.6 |
| 18 | 0.650 | 0.050 | 5 | 0.75 | 20 | 0.100 | 4.0 | 40 | 1.0 |
| 101 | 0.300 | 0.010 | 10 | 0.40 | 11 | 0.100 | 1.1 | 24 | 0.5 |
| 102 | 0.350 | 0.004 | 10 | 0.40 | 11 | 0.050 | 1.1 | 24 | 0.5 |
| 103 | 0.700 | 0.100 | 30 | 0.75 | 150 | 0.050 | 5.0 | 75 | 13.5 |
| 104 | 0.650 | 0.120 | 30 | 0.75 | 150 | 0.100 | 5.0 | 75 | 13.5 |
| 105 | 0.350 | 0.010 | 10 | 0.35 | 11 | 0.000 | 1.1 | 24 | 0.5 |
| 106 | 0.650 | 0.100 | 30 | 0.80 | 150 | 0.150 | 5.0 | 75 | 13.5 |
| 107 | 0.500 | 0.000 | 5 | 0.55 | 4 | 0.050 | 0.8 | 100 | 0.9 |
| 108 | 0.500 | 0.040 | 900 | — | — | — | — | 1 | 0.9 |
| 109 | — | — | — | 0.55 | 900 | — | — | 1 | 0.9 |

TABLE 2

| | | | | | | Cutting |
|---|---|---|---|---|---|---|
| | Second Layer | | Third Layer | | Thickness of | Test 1 |
| Sample | | Thickness | | Thickness | Coating Film | Time |
| No. | Composition | [μm] | Composition | [μm] | [μm] | [Min] |
| 1 | — | — | — | — | 0.5 | 85 |
| 2 | — | — | — | — | 2.0 | 90 |
| 3 | — | — | — | — | 22.0 | 81 |
| 4 | — | — | — | — | 15.0 | 113 |
| 5 | — | — | — | — | 1.6 | 91 |
| 6 | — | — | — | — | 1.0 | 90 |
| 7 | — | — | — | — | 13.5 | 110 |
| 8 | — | — | — | — | 12.5 | 107 |
| 9 | — | — | — | — | 4.0 | 99 |
| 10 | — | — | — | — | 0.9 | 88 |
| 11 | — | — | — | — | 3.2 | 98 |
| 12 | — | — | — | — | 3.2 | 94 |
| 13 | — | — | — | — | 5.0 | 101 |
| 14 | Same as First Unit Layer | 0.1 | — | — | 2.1 | 102 |
| 15 | Same as Second Unit Layer | 1.0 | — | — | 23.0 | 90 |
| 16 | — | — | TiCN | 0.1 | 15.1 | 123 |
| 17 | — | — | TiAlScCN | 1.0 | 2.6 | 105 |
| 18 | Same as First Unit Layer | 1 | TiAlScCN | 0.1 | 2.1 | 103 |
| 101 | — | — | — | — | 0.5 | 30 |
| 102 | — | — | — | — | 0.5 | 28 |
| 103 | — | — | — | — | 13.5 | 35 |
| 104 | — | — | — | — | 13.5 | 32 |
| 105 | — | — | — | — | 0.5 | 28 |
| 106 | — | — | — | — | 13.5 | 32 |
| 107 | — | — | — | — | 0.9 | 25 |
| 108 | — | — | — | — | 0.9 | 23 |
| 109 | — | — | — | — | 0.9 | 27 |

### <<Evaluation>>

For the cutting tool of each sample, the compositions of the first unit layer, the second unit layer, the second layer, and the third layer, each of the number of the first unit layers stacked and the number of the second unit layers stacked, the average thickness of the first unit layers, the average thickness of the second unit layers, the thickness of the first layer, the thickness of the second layer, the thickness of the third layer, and λ2/λ1 were measured by the methods described in the first embodiment. Results are shown in Tables 1 and 2.

When “TiAlScCN” was described with regard to the third layer, the atomic ratio of Ti, Al, and Sc in the third layer was the same as the atomic ratio of Ti, Al, and Sc in the first unit layer. The indication that the number of stacked layers is 10 indicates that the alternating layer includes 10 first unit layers and 10 second unit layers. When “-” is described in the column “λ2/λ1”, it means that at least one of each of the first unit layers and each of the second unit layers is not present.

In each of samples 1 to 18, the crystal structures of the first unit layer and the second unit layer were confirmed by performing XRD measurement onto the first unit layer of the cutting tool of each sample. A specific method is as described in the first embodiment. In each of these samples, it was confirmed that the first unit layer had a cubic crystal structure and the second unit layer had a cubic crystal structure.

In each of samples 1 to 18, the hardness of the coating film was measured by the method described in the first embodiment. It was confirmed that the hardness of the coating film of each of these samples was within a range of 30 GPa or more and 55 GPa or less.

In each of samples 1 to 18, the compressive residual stress of the coating film was measured by the method described in the first embodiment. It was confirmed that the absolute value of the compressive residual stress of the coating film of each of these samples was 6 GPa or less.

### <Cutting Test 1: Continuous Turning Test (Wet Type)>

A continuous turning test was performed onto each of the cutting tools of the samples each with a shape of CNMG120408 under the following cutting conditions, so as to measure a time until a flank face wear amount of the cutting edge became 0.2 mm. Results are shown in Table 2. A longer cutting time represents a longer tool life.

### <<Cutting Conditions>>

Workpiece: Inconel 718 (HB400)
Cutting rate: 95 m/min
Feeding rate: 0.2 mm/rev
Cut-in: 1.5 mm
Coolant: water-soluble

The cutting performed under the above cutting conditions is high-efficiency processing of a difficult-to-cut material and corresponds to cutting performed under such conditions that the cutting edge temperature becomes high.

The cutting tools of samples 1 to 18 correspond to examples of the present disclosure, and the cutting tools of samples 101 to 109 correspond to comparative examples. It was confirmed that in the cutting performed under such conditions that the cutting edge temperature becomes high, each of the cutting tools of samples 1 to 18 had a longer tool life than those of the cutting tools of samples 101 to 109.

### Example 2

### <Samples 21 to 40 and Samples 121 to 139>

A coating film was formed on a substrate using the same cathode arc ion plating apparatus as in Example 1. Cathode 106 consists of Ti, Al, and Sc, and a ratio of the respective elements is adjusted so as to obtain the composition of the first unit layer in Tables 3 and 4. Cathode 107 consists of Al, V, and Si or B, and a ratio of the respective elements is adjusted so as to obtain the composition of the third unit layer in Tables 3 and 4. The composition of cathode 120 is Ti.

A chip, which is a cemented carbide having a grade of K20 of the JIS standards and having a shape of CNMG120408 of the JIS standards, was attached on substrate holder 104 as the substrate, and the substrate was cleaned by the same method as in Example 1, thereby preparing the substrate.

Next, under the same conditions as in Example 1, a B layer and a C layer having compositions shown in Tables 5 and 6, and an A layer having a composition shown in Tables 3 and 4 were formed on the substrate, thereby obtaining a cutting tool of each sample.

TABLE 3

| | A Layer | | | | | | | | | | |
|---|---|---|---|---|---|---|---|---|---|---|---|
| | First Unit Layer | | | Third Unit Layer | | | | | | | |
| | (Ti_{1-a-b}AlₐSc_{b}N) | | | (Al_{d}V_{1-d-e}MₑN) | | | | | | | |
| | | | Average | | | | Average | | | Number of | |
| Sample | | | Thickness | | | | Thickness | | | Stacked | Thickness |
| No. | a | b | [nm] | d | e | M | [nm] | d − a | λ3/λ1 | Layers | [μm] |
| 21 | 0.350 | 0.010 | 10 | 0.40 | 0.01 | Si | 11 | 0.050 | 1.1 | 24 | 0.5 |
| 22 | 0.350 | 0.010 | 10 | 0.40 | 0.01 | B | 11 | 0.050 | 1.1 | 24 | 0.5 |
| 23 | 0.350 | 0.050 | 2 | 0.45 | 0.02 | B | 2 | 0.100 | 1.0 | 500 | 2.0 |
| 24 | 0.350 | 0.100 | 50 | 0.50 | 0.03 | Si | 60 | 0.150 | 1.2 | 200 | 22.0 |
| 25 | 0.500 | 0.050 | 100 | 0.55 | 0.04 | B | 150 | 0.050 | 1.5 | 60 | 15.0 |
| 26 | 0.650 | 0.010 | 30 | 0.70 | 0.05 | Si | 90 | 0.050 | 3.0 | 13 | 1.6 |
| 27 | 0.650 | 0.050 | 5 | 0.75 | 0.01 | B | 20 | 0.100 | 4.0 | 40 | 1.0 |
| 28 | 0.650 | 0.100 | 30 | 0.75 | 0.02 | Si | 150 | 0.100 | 5.0 | 75 | 13.5 |
| 29 | 0.650 | 0.100 | 30 | 0.75 | 0.02 | B | 150 | 0.100 | 5.0 | 75 | 13.5 |
| 30 | 0.400 | 0.020 | 5 | 0.70 | 0.03 | B | 20 | 0.300 | 4.0 | 500 | 12.5 |
| 31 | 0.450 | 0.030 | 200 | 0.65 | 0.04 | Si | 200 | 0.200 | 1.0 | 10 | 4.0 |
| 32 | 0.500 | 0.040 | 5 | 0.55 | 0.05 | B | 4 | 0.050 | 0.8 | 100 | 0.9 |
| 33 | 0.350 | 0.070 | 30 | 0.40 | 0.05 | Si | 150 | 0.050 | 5.0 | 18 | 3.2 |
| 34 | 0.400 | 0.080 | 5 | 0.65 | 0.03 | B | 30 | 0.250 | 6.0 | 90 | 3.2 |
| 35 | 0.500 | 0.100 | 250 | 0.60 | 0.01 | Si | 250 | 0.100 | 1.0 | 10 | 5.0 |
| 36 | 0.350 | 0.050 | 2 | 0.45 | 0.02 | B | 2 | 0.100 | 1.0 | 500 | 2.0 |
| 37 | 0.350 | 0.100 | 50 | 0.50 | 0.03 | Si | 60 | 0.150 | 1.2 | 200 | 22.0 |
| 38 | 0.500 | 0.050 | 100 | 0.55 | 0.04 | B | 150 | 0.050 | 1.5 | 60 | 15.0 |
| 39 | 0.650 | 0.010 | 30 | 0.70 | 0.05 | Si | 90 | 0.050 | 3.0 | 13 | 1.6 |
| 40 | 0.650 | 0.050 | 5 | 0.75 | 0.01 | B | 20 | 0.100 | 4.0 | 40 | 1.0 |

TABLE 4

| | A Layer | | | | | | | | | | |
|---|---|---|---|---|---|---|---|---|---|---|---|
| | First Unit Layer | | | Third Unit Layer | | | | | | | |
| | (Ti_{1-a-b}AlₐSc_{b}N) | | | (Al_{d}V_{1-d-e}MₑN) | | | | | | | |
| | | | Average | | | | Average | | | Number of | |
| Sample | | | Thickness | | | | Thickness | | | Stacked | Thickness |
| No. | a | b | [nm] | d | e | M | [nm] | d − a | λ3/λ1 | Layers | [μm] |
| 121 | 0.300 | 0.010 | 10 | 0.40 | 0.01 | Si | 11 | 0.100 | 1.1 | 24 | 0.5 |
| 122 | 0.350 | 0.004 | 10 | 0.40 | 0.01 | Si | 11 | 0.050 | 1.1 | 24 | 0.5 |
| 123 | 0.300 | 0.010 | 10 | 0.40 | 0.01 | B | 11 | 0.100 | 1.1 | 24 | 0.5 |
| 124 | 0.350 | 0.004 | 10 | 0.40 | 0.01 | B | 11 | 0.050 | 1.1 | 24 | 0.5 |
| 125 | 0.700 | 0.100 | 30 | 0.75 | 0.02 | Si | 150 | 0.050 | 5.0 | 75 | 13.5 |
| 126 | 0.650 | 0.120 | 30 | 0.75 | 0.02 | Si | 150 | 0.100 | 5.0 | 75 | 13.5 |
| 127 | 0.700 | 0.100 | 30 | 0.75 | 0.02 | B | 150 | 0.050 | 5.0 | 75 | 13.5 |
| 128 | 0.650 | 0.120 | 30 | 0.75 | 0.02 | B | 150 | 0.100 | 5.0 | 75 | 13.5 |
| 129 | 0.350 | 0.010 | 10 | 0.35 | 0.01 | Si | 11 | 0.000 | 1.1 | 24 | 0.5 |
| 130 | 0.350 | 0.010 | 10 | 0.35 | 0.01 | B | 11 | 0.000 | 1.1 | 24 | 0.5 |
| 131 | 0.650 | 0.100 | 30 | 0.80 | 0.02 | Si | 150 | 0.150 | 5.0 | 75 | 13.5 |
| 132 | 0.650 | 0.100 | 30 | 0.80 | 0.02 | B | 150 | 0.150 | 5.0 | 75 | 13.5 |
| 133 | 0.500 | 0.040 | 5 | 0.55 | 0.06 | B | 4 | 0.050 | 0.8 | 100 | 0.9 |
| 134 | 0.350 | 0.070 | 30 | 0.40 | 0.06 | Si | 150 | 0.050 | 5.0 | 18 | 3.2 |
| 135 | 0.500 | 0.000 | 5 | 0.55 | 0.05 | B | 4 | 0.050 | 0.8 | 100 | 0.9 |
| 136 | 0.350 | 0.000 | 30 | 0.40 | 0.05 | Si | 150 | 0.050 | 5.0 | 18 | 3.2 |
| 137 | 0.500 | 0.040 | 900 | — | — | — | — | — | — | 1 | 0.9 |
| 138 | — | — | — | 0.55 | 0.05 | B | 900 | — | — | 1 | 0.9 |
| 139 | — | — | — | 0.40 | 0.05 | Si | 3200 | — | — | 1 | 3.2 |

TABLE 5

| | | | | | Thickness | Cutting |
|---|---|---|---|---|---|---|
| | B Layer | | C Layer | | of Coating | Test 2 |
| Sample | | Thickness | | Thickness | Film | Time |
| No. | Composition | [μm] | Composition | [μm] | [μm] | [Min] |
| 21 | — | — | — | — | 0.5 | 75 |
| 22 | — | — | — | — | 0.5 | 85 |
| 23 | — | — | — | — | 2.0 | 86 |
| 24 | — | — | — | — | 22.0 | 94 |
| 25 | — | — | — | — | 15.0 | 95 |
| 26 | — | — | — | — | 1.6 | 82 |
| 27 | — | — | — | — | 1.0 | 80 |
| 28 | — | — | — | — | 13.5 | 106 |
| 29 | — | — | — | — | 13.5 | 110 |
| 30 | — | — | — | — | 12.5 | 104 |
| 31 | — | — | — | — | 4.0 | 92 |
| 32 | — | — | — | — | 0.9 | 78 |
| 33 | — | — | — | — | 3.2 | 90 |
| 34 | — | — | — | — | 3.2 | 89 |
| 35 | — | — | — | — | 5.0 | 97 |
| 36 | Same as First Unit Layer | 0.1 | — | — | 2.1 | 92 |
| 37 | Same as Second Unit Layer | 1.0 | — | — | 23.0 | 102 |
| 38 | — | — | TiCN | 0.1 | 15.1 | 106 |
| 39 | — | — | TiAlScCN | 1.0 | 2.6 | 94 |
| 40 | Same as First Unit Layer | 1.0 | TiAlScCN | 0.1 | 2.1 | 91 |

TABLE 6

| | | | | | Thickness | Cutting |
|---|---|---|---|---|---|---|
| | B Layer | | C Layer | | of Coating | Test 2 |
| Sample | | Thickness | | Thickness | Film | Time |
| No. | Composition | [μm] | Composition | [μm] | [μm] | [Min] |
| 121 | — | — | — | — | 0.5 | 17 |
| 122 | — | — | — | — | 0.5 | 14 |
| 123 | — | — | — | — | 0.5 | 16 |
| 124 | — | — | — | — | 0.5 | 14 |
| 125 | — | — | — | — | 13.5 | 18 |
| 126 | — | — | — | — | 13.5 | 17 |
| 127 | — | — | — | — | 13.5 | 19 |
| 128 | — | — | — | — | 13.5 | 18 |
| 129 | — | — | — | — | 0.5 | 16 |
| 130 | — | — | — | — | 0.5 | 14 |
| 131 | — | — | — | — | 13.5 | 15 |
| 132 | — | — | — | — | 13.5 | 17 |
| 133 | — | — | — | — | 0.9 | 20 |
| 134 | — | — | — | — | 3.2 | 25 |
| 135 | — | — | — | — | 0.9 | 22 |
| 136 | — | — | — | — | 3.2 | 24 |
| 137 | — | — | — | — | 0.9 | 15 |
| 138 | — | — | — | — | 0.9 | 13 |
| 139 | — | — | — | — | 3.2 | 12 |

<<Evaluation>>5 For the cutting tool of each sample, the compositions of the first unit layer, the third unit layer, the B layer, and the C layer, each of the number of the first unit layers stacked and the number of the third unit layers stacked, the average thickness of the first unit layers, the average thickness of the third unit layers, the thickness of the A layer, the thickness of the B layer, the thickness of the C layer, and λ3/λ1 were measured by the same methods as in Example 1. Results are shown in Tables 3 to 6. In each of samples 21 to 40, it was confirmed that each of the first unit layer and the second unit layer had a cubic crystal structure. It was confirmed that the hardness of the coating film of each of samples 21 to 40 was in a range of 30 GPa or more and 55 GPa or less. It was confirmed that the absolute value of the compressive residual stress of the coating film of each of samples 21 to 40 was 6 GPa or less.

### <Cutting Test 2: Continuous Turning Test (Dry Type)>

A continuous turning test was performed onto each of the cutting tools of the samples each with a shape of CNMG120408 under the following cutting conditions, so as to measure a time until a flank face wear amount of the cutting edge became 0.2 mm. Results are shown in Table 2. A longer cutting length represents a longer tool life.

### <<Cutting Conditions>>

Workpiece: Inconel 718 (HB400)
Cutting rate: 70 m/min
Feeding rate: 0.15 mm/rev
Cut-in: 1.0 mm
Dry processing

The cutting performed under the above cutting conditions is high-efficiency processing of a difficult-to-cut material and corresponds to cutting performed under such conditions that the cutting edge temperature becomes high.

The cutting tools of samples 21 to 40 correspond to examples of the present disclosure, and the cutting tools of samples 121 to 139 correspond to comparative examples. It was confirmed that in the cutting performed under such conditions that the cutting edge temperature becomes high, each of the cutting tools of samples 21 to 40 had a longer tool life than those of the cutting tools of samples 121 to 139.

Heretofore, the embodiments and examples of the present disclosure have been illustrated, but it has been initially expected to appropriately combine the configurations of the embodiments and examples and modify them in various manners.

The embodiments and examples disclosed herein are illustrative and non-restrictive in any respect. The scope of the present invention is defined by the terms of the claims, rather than the embodiments and examples described above, and is intended to include any modifications within the scope and meaning equivalent to the terms of the claims.

### REFERENCE SIGNS LIST

1 cutting tool; 2 substrate; 3 coating film; 12 first unit layer, 13 first layer, 13A A layer, 14 third layer, 14C C layer, 15 second unit layer, 16 second layer, 16B B layer, 17 third unit layer, 101 chamber, 102 gas; 103 gas discharging port; 104 substrate holder, 105 gas introduction port; 106, 107, 120 cathode; 108, 109 arc power supply; 110 bias power supply.

1. A cutting tool comprising: a substrate; and a coating film disposed on the substrate, wherein
the coating film includes a first layer,
the first layer consists of an alternating layer in which a first unit layer and a second unit layer are alternately stacked,
the first unit layer consists of Ti_{1-a-b}AlₐSc_{b}N,
the a is 0.350 or more and 0.650 or less,
the b is 0.010 or more and 0.100 or less,
the second unit layer consists of Al_{c}V_{1-c}N,
the c is 0.40 or more and 0.75 or less, and
the a and the c satisfy a relation of c>a.

2. The cutting tool according to claim 1, wherein in the first unit layer and the second unit layer adjacent to the first unit layer, a ratio λ2/λ1 of a thickness λ2 of the second unit layer to a thickness λ1 of the first unit layer is 1 or more and 5 or less.

3. The cutting tool according to claim 1, wherein
an average thickness of the first unit layer is 2 nm or more and 200 nm or less, and
an average thickness of the second unit layer is 2 nm or more and 200 nm or less.

4. The cutting tool according to claim 1, wherein
the coating film further includes a second layer disposed between the substrate and the first layer,
a composition of the second layer is the same as a composition of any of the first unit layer and the second unit layer,
a thickness of the second layer is larger than an average thickness of the unit layer having the same composition as the composition of the second layer, and
the thickness of the second layer is 0.1 μm or more and 1.0 μm or less.

5. The cutting tool according to claim 1, wherein
the coating film further includes a third layer provided on a side of the first layer opposite to the substrate,
the third layer consists of TiCN or TiAlScCN, and
a thickness of the third layer is 0.1 μm or more and 1.0 μm or less.

6. The cutting tool according to claim 1, wherein a thickness of the first layer is 0.5 μm or more and 15 μm or less.

7. A cutting tool comprising: a substrate; and a coating film disposed on the substrate, wherein
the coating film includes an A layer,
the A layer consists of an alternating layer in which a first unit layer and a third unit layer are alternately stacked,
the first unit layer consists of Ti_{1-a-b}AlₐSc_{b}N,
the a is 0.350 or more and 0.650 or less,
the b is 0.010 or more and 0.100 or less,
the third unit layer consists of Al_{d}V_{1-d-e}MₑN,
the M is silicon or boron,
the d is 0.40 or more and 0.75 or less,
the e is more than 0 and 0.05 or less, and
the a and the d satisfy a relation of d>a.

8. The cutting tool according to claim 7, wherein in the first unit layer and the third unit layer adjacent to the first unit layer, a ratio λ3/λ1 of a thickness λ3 of the third unit layer to a thickness λ1 of the first unit layer is 1 or more and 5 or less.

9. The cutting tool according to claim 7, wherein the M is silicon.

10. The cutting tool according to claim 7, wherein the M is boron.

11. The cutting tool according to claim 7, wherein
an average thickness of the first unit layer is 2 nm or more and 200 nm or less, and
an average thickness of the third unit layer is 2 nm or more and 200 nm or less.

12. The cutting tool according to claim 7, wherein
the coating film further includes a B layer disposed between the substrate and the A layer,
a composition of the B layer is the same as a composition of any of the first unit layer and the third unit layer,
a thickness of the B layer is larger than an average thickness of the unit layer having the same composition as the composition of the B layer, and
the thickness of the B layer is 0.1 μm or more and 1 μm or less.

13. The cutting tool according to claim 7, wherein
the coating film further includes a C layer provided on a side of the A layer opposite to the substrate,
the C layer consists of TiCN or TiAlScCN, and
a thickness of the C layer is 0.1 μm or more and 1.0 μm or less.

14. The cutting tool according to claim 7, wherein a thickness of the A layer is 0.5 μm or more and 15 μm or less.
